(19) United States
(12) Patent Application Publication
(10) Pub. No.: US 2008/0115355 A1
(43) Pub. Date: May 22, 2008

(54) Method of manufacturing printed circuit board

(75) Inventors: Jung-Hyun Park, Suwon-si (KR); Byoung-Youl Min, Seongnam-si (KR); Je-Gwang Yoo, Yongin-si (KR); Myung-Sam Kang, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/984,209

(22) Filed: Nov. 14, 2007

(30) Foreign Application Priority Data
Nov. 21, 2006 (KR) 10-2006-0115402

(51) Int. Cl. H05K 3/10; H01K 3/10

(52) U.S. Cl. 29/852; 29/846; 29/831

(57) ABSTRACT

A method of manufacturing a printed circuit board is disclosed. Using the method, which includes embedding a first circuit pattern and a second circuit pattern in one side and the other side of an insulation substrate, forming a via hole by removing portions of the insulation substrate and the first circuit pattern, and electrically connecting the first circuit pattern and the second circuit pattern by forming a plating layer in the via hole, it is possible to form high-density circuits, as circuitry may be formed in portions that might have been occupied by lands, and more circuitry may be implemented for a given area of insulation substrate, whereby a fine-patterned printed circuit board may be implemented that has a high degree of integration. Also, a printed circuit board can be produced which allows good signal transfers between layers and with which fine circuit patterns can be implemented with inexpensive costs.

### CROSS-REFERENCE TO RELATED APPLICATIONS

This application claims the benefit of Korean Patent Application No. 10-2006-0115402 filed with the Korean Intellectual Property Office on Nov. 21, 2006, the disclosure of which is incorporated herein by reference in its entirety.

### BACKGROUND

1. Technical Field

The present invention relates to a method of manufacturing a printed circuit board.

2. Description of the Related Art

With advances in the electronics industry, the demands are growing for smaller components having greater functionality. In step with this trend, there is a demand also for higher density circuits on printed circuit boards, and thus various processes are being used which implement fine circuits.

One of the fields of the electronics industry in which this trend is the most marked is the field of mobile phones, which is trending towards smaller dimensions and thicknesses. Consequently, the components used in mobile phones are also trending towards smaller dimensions in accordance with such trend. In particular, the number of cases have started to increase in which a mobile phone employs a CSP (chip scale package), which is a board used as an interposer in an IC (integrated circuit), so that currently, almost all packages are using CSP boards, with the demand growing for increased board density.

In many cases, vias may be required for increasing density, which interconnect layers to transfer electrical signals. However, in order to implement vias, lands may need to be formed in consideration of the apparatus used in the manufacturing process and tolerances in the product, where these lands act as obstacles to implementing a greater amount of circuitry.

FIG. 1 is a perspective view of a printed circuit board according to the related art. As shown in the figure, an upper land is used around the via processed for interlayer electrical connection, because of processing tolerances during the exposure and development processes. Referring to FIG. 1, the size of the land is approximately the tolerances for the exposure and development processes added to the size of the via. Although high-precision exposure equipment may be used to decrease the size of the lands, the use of such equipment does not allow a complete removal of the lands.

Conventional circuit patterns may be implemented by subtractive methods and semi-additive methods, but both types entail upper lands around the via holes due to the processing tolerances that occur during the exposure and development processes.

As there is a limit to decreasing the size of the lands, finer circuits may be needed, but implementing fine circuits may cause several problems, such as having to develop the necessary apparatus, high investment, and complicated processes, as well as the resulting increase in defects. Also, the cost may be higher for products in which fine circuits are applied, which may pose a problem for increased profits.

### SUMMARY

An aspect of the invention is to provide a method of manufacturing a printed circuit board, which allows good signal transfers between layers and with which fine circuit patterns can be implemented with inexpensive costs, without forming lands around vias that hamper density increase.

One aspect of the invention provides a method of manufacturing a printed circuit board, which includes embedding a first circuit pattern and a second circuit pattern in one side and the other side of an insulation substrate, forming a via hole by removing portions of the insulation substrate and the first circuit pattern, and electrically connecting the first circuit pattern and the second circuit pattern by forming a plating layer in the via hole.

Embedding the first circuit pattern and the second circuit pattern may include forming the first circuit pattern on a first carrier board, on which a first seed layer is formed, and forming the second circuit pattern on a second carrier board, on which a second seed layer is formed; stacking the first carrier board on one side of the insulation substrate, such that the first circuit pattern is embedded in one side of the insulation substrate, and stacking the second carrier board on the other side of the insulation substrate, such that the second circuit pattern is embedded in the other side of the insulation substrate; removing the first and second carrier boards; and removing the first and second seed layers.

Electrically connecting the first and second circuit patterns may include stacking a conductive third seed layer on a hole wall of the via hole, stacking plating resist on a surface of the insulation substrate such that a portion corresponding to the via hole is opened, forming the plating layer in the via hole, removing a portion of the plating layer such that the plating layer is substantially level with a surface of the insulation substrate, removing the plating resist, and removing the exposed third seed layer.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a perspective view of a printed circuit board according to the related art.

FIG. 2 is a flowchart illustrating a method of forming a circuit pattern in a printed circuit board according to an embodiment of the invention.

FIG. 3A, FIG. 3B, FIG. 3C, and FIG. 3D represent a flow diagram illustrating a method of forming a circuit pattern in a printed circuit board according to an embodiment of the invention.

FIG. 4 is a flowchart illustrating a method of manufacturing a printed circuit board according to an embodiment of the invention.

FIG. 5A, FIG. 5B, FIG. 5C, FIG. 5D, FIG. 5E, FIG. 5F, FIG. 5G and FIG. 5H represent a flow diagram illustrating a process of manufacturing a printed circuit board according to an embodiment of the invention.

FIG. 6A is a plan view of the printed circuit board illustrated in FIG. 5B.

FIG. 6B is a plan view of the printed circuit board illustrated in FIG. 5H.

FIG. 7A is a cross-sectional view of a printed circuit board according to another embodiment of the invention.

FIG. 7B is a plan view of a printed circuit board according to another embodiment of the invention.

FIG. 8 is a perspective view of a printed circuit board according to an embodiment of the invention.

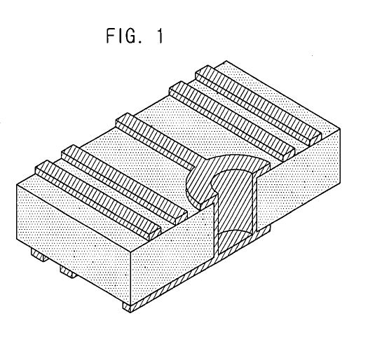

### DETAILED DESCRIPTION

The method of manufacturing a printed circuit board according to certain embodiments of the invention will be described below in more detail with reference to the accompanying drawings, in which those components are rendered the same reference number that are the same or are in correspondence, regardless of the figure number, and redundant explanations are omitted.

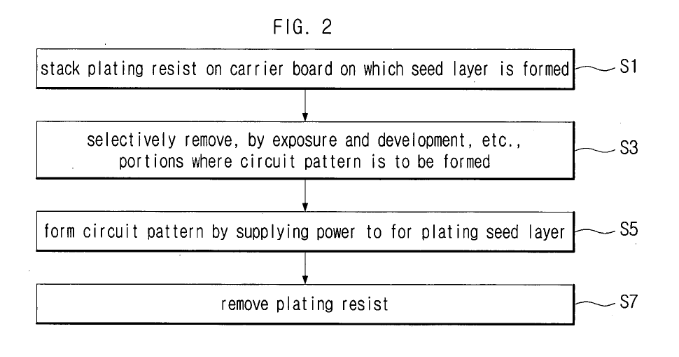

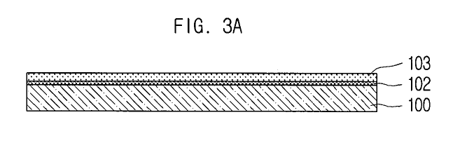

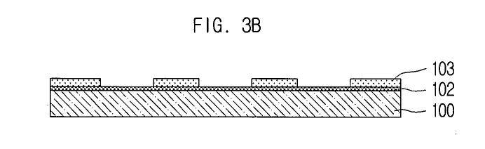

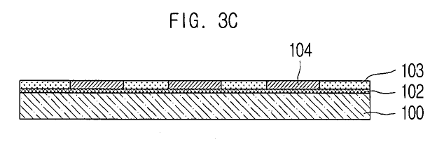

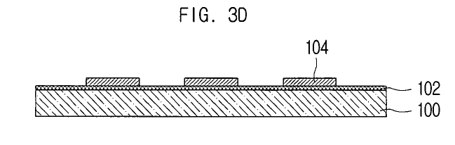

FIG. 2 is a flowchart illustrating a method of forming a circuit pattern in a printed circuit board according to an embodiment of the invention, and FIGS. 3A to 3D represent a flow diagram illustrating a method of forming a circuit pattern in a printed circuit board according to an embodiment of the invention. In FIGS. 3A to 3D are illustrated a carrier board 100, a seed layer 102, a circuit pattern 104, plating resist 103, and a plating layer 104.

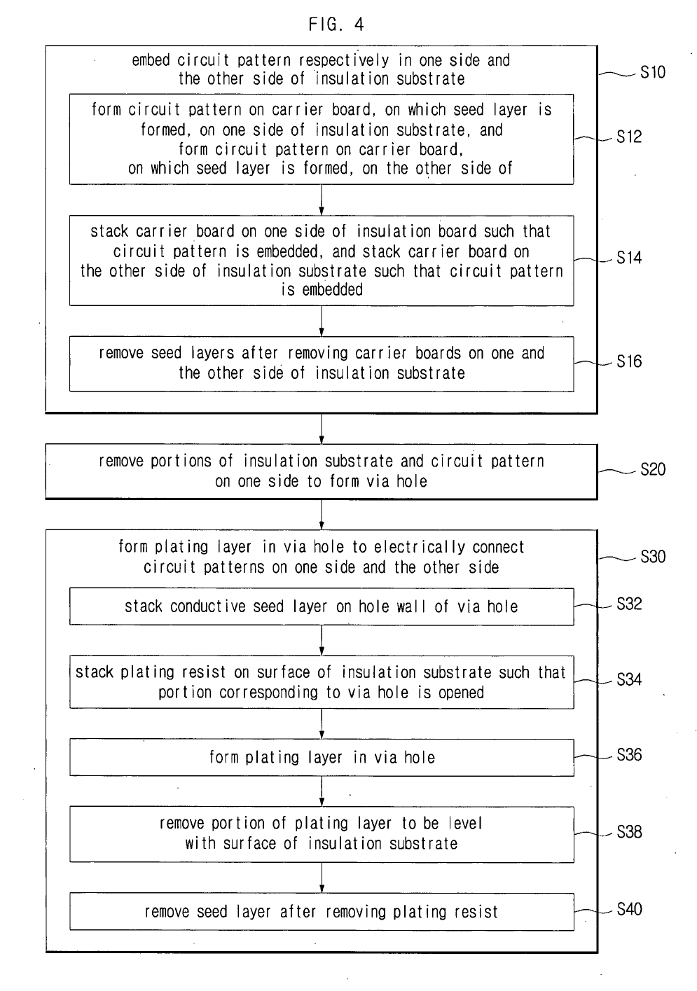

The method of forming a circuit pattern on a printed circuit board based on this embodiment may include a method of embedding the circuit pattern in the insulation substrate, such as that illustrated with reference to FIG. 4 described later. Before describing the circuit pattern embedded in the insulation substrate, the method of forming the circuit pattern will first be described.

For the method of forming the circuit pattern 104 on the carrier board 100, an additive method may be used, where operation S1 of FIG. 2 is illustrated in FIG. 3A, in which plating resist 103 is stacked on a carrier board 100, on a surface of which a seed layer 102 is formed.

The seed layer 102 corresponds to the layer that serves as a base for electroplating. As the carrier board 100 is typically made of a nonconductor of electricity, an electroless plated layer, i.e. the seed layer 102, may be stacked beforehand so that a plating layer may be deposited by electroplating. If the carrier board 100 is made of a conductor and the carrier board 100 is such that can readily be peeled off after embedding the circuit pattern 104 in the insulation substrate 106, the process of forming the seed layer 102 according to this embodiment may be omitted.

The plating resist 103 here may be a photosensitive material used for implementing a circuit pattern by additive method, and thus can be said to have a different purpose from that of the plating resist described later.

Next, operation S3 of FIG. 2, of selectively removing portions where the circuit pattern 104 is to be formed by exposure and development, etc., is illustrated in FIG. 3B. By removing the plating resist 103, the carrier plate 100 may be exposed along the positions where the circuit pattern 104 is to be formed.

Operation S5 of FIG. 2 is in correspondence with FIG. 3C, where power may be supplied to the seed layer 102 so that it is plated, and operation S7 of FIG. 2 is in correspondence with FIG. 3D, where the circuit pattern 104 may be formed after removing the plating resist 103.

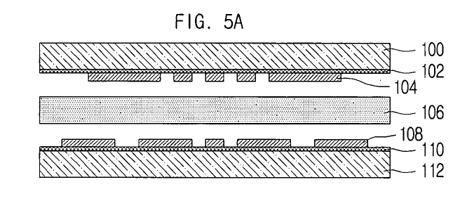

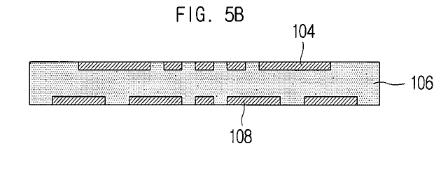

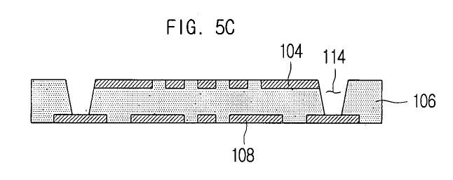

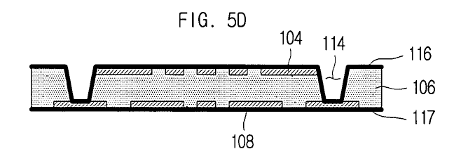

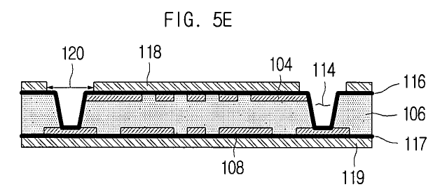

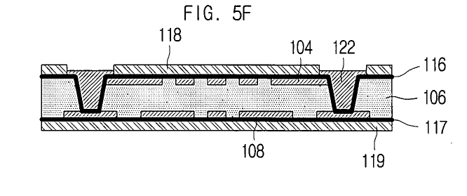

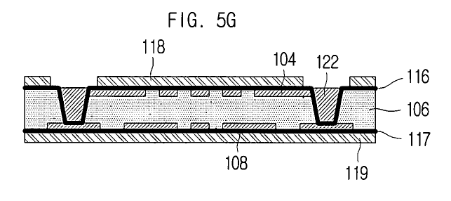

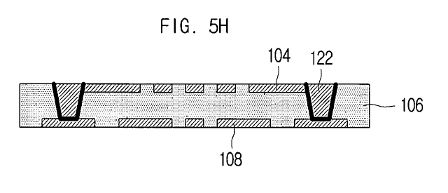

FIG. 4 is a flowchart illustrating a method of manufacturing a printed circuit board according to an embodiment of the invention, and FIGS. 5A to 5H is a flow diagram illustrating a process of manufacturing a printed circuit board according to an embodiment of the invention, while FIG. 6A is a plan view of the printed circuit board illustrated in FIG. 5B, and FIG. 6B is a plan view of the printed circuit board illustrated in FIG. 5H.

In FIGS. 5A to 5H and FIGS. 6A and 6B are illustrated carrier boards 100, 112, seed layers 102, 110, 116, 117, circuit patterns 104, 108, an insulation substrate 106, via holes 114, plating resist 118, 119, portions 120 corresponding with the via holes, a plating layer 122, and via processing regions 105.

In this embodiment, by removing portions of the insulation substrate and a circuit pattern embedded in the insulation substrate to form via holes, and then forming a plating layer in the via holes, there are no lands formed that protrude out around the via, whereby interlayer signal transfers can be made easier, and fine patterns can be implemented without having to proceed through complicated processes.

To this end, first, a circuit pattern 104, 108 may be embedded each in one side and the other side of an insulation substrate 106 (S10). Processes corresponding to operation S10 of FIG. 4 are illustrated in FIGS. 5A and 5B.

Forming the circuit patterns 104, 108 may be performed using the method described with reference to FIG. 2 and FIGS. 3A to 3D. Embedding the circuit patterns 104, 108 thus formed may include forming a circuit pattern 104 on a carrier board 100, having a seed layer 102 formed thereon, on one side of the insulation substrate 106, and forming a circuit pattern 108 on a carrier board 112, having a seed layer 110 formed thereon, on the other side of the insulation substrate 106 (S12).

Next, as shown in FIG. 5A, the carrier board 100 may be stacked on such that the circuit pattern 104 is embedded in one side of the insulation substrate 106, and the carrier board 112 may be stacked on such that the circuit pattern 108 is embedded in the other side of the insulation substrate 106 (S14).

As such, in this embodiment, the printed circuit board may be manufactured to have embedded patterns, whereby the overall thickness of the board may be decreased. Also, since the circuit patterns 104, 108 may be contained within the insulation substrate 106, the ion migration phenomenon may be reduced, and as fine patterns may be implemented, the degree of freedom may be increased in designing the printed circuit board.

In order to embed the circuit patterns 104, 108 more securely in the insulation substrate 106, it may be advantageous to heat the insulation substrate 106 to a particular temperature range according to the material used for the insulation substrate 106.

Next, after embedding the circuit patterns 104, 108 in the insulation substrate 106, the carrier boards 100, 112 on the one and the other sides of the insulation substrate 106 may be removed (S16), and the seed layers 102, 110 of the one and the other sides of the insulation substrate 106 may be removed, to expose the circuit patterns 104, 108 at the surfaces of the insulation substrate 106.

A process corresponding to operation S20 of FIG. 4 is illustrated in FIG. 5C.

When implementing interlayer electrical connection between circuit patterns 104, 108, the carrier boards 100, 112 may be removed, and via holes 114 may be perforated (S20) in the insulation substrate 106 on which the circuit patterns 104, 108 are exposed, by removing portions of the insulation substrate 106 and a circuit pattern 104 of one side, as shown in FIG. 5C. After performing surface treatment processes, such as desmearing, etc., the inner perimeters of the via holes 114 may be plated, or a conductive material may be filled in the via holes 114, for electrical connection through the via holes 114.

Regarding the positions where the via holes 114 are perforated in the insulation substrate 106, it is described for this embodiment that portions of the insulation substrate 106 and a circuit pattern 104 of one side may be removed to perforate the via holes 114. Here, the portions of the circuit pattern 104 include predetermined portions of the circuit pattern 104, which means that the via holes 114 may be processed to include minimal portions of the circuit pattern 104, such that the via holes 114 need not be formed in separation from the circuit pattern 104.

Thus, referring to FIGS. 5B and 5C, the positions that correspond with the positions of the via holes that will be perforated are depicted using dotted lines, as illustrated in FIG. 5B. As illustrated in the figure, the via holes 114 to be perforated may be formed by removing a portion of the circuit pattern 104 formed on one side of the insulation substrate 106.

The positions where the via holes 114 are to be perforated may be seen from another perspective with reference to FIG. 6A, where FIG. 6A is a plan view of the printed circuit board illustrated in FIG. 5B. As illustrated in the figure, the via holes 114 that are to be formed including portions of the circuit pattern 104 are depicted by dotted lines to represent via processing regions

Therefore, because the via processing regions 105 may be connected with portions of the circuit pattern 104, there do not have to be any protruding lands formed around the via holes, when forming a plating layer 122 in the via holes 114 and embedding in the insulation substrate 106. Thus, it is possible to form high-density circuits, as circuitry may be formed in portions that might have been occupied by lands, and more circuitry may be implemented for a given area of insulation substrate, whereby a fine-patterned printed circuit board may be implemented that has a high degree of integration.

Processes corresponding to operation S30 of FIG. 4 are illustrated in FIGS. 5D through 5H.

After perforating the via holes 114, in order to form a plating layer in the via holes 114 and electrically connect the circuit patterns 104, 108 in the one and the other sides (S30), a conductive seed layer 116 may be stacked by performing electroless plating on the hole walls of the via holes 114 (S32), as shown in FIG. 5D, and a seed layer 117 may be stacked also on the other side of the insulation substrate 106.

After stacking the seed layers 116, 117, plating resist 118 may be stacked on the surface of the insulation substrate 106, as in FIG. 5E, such that portions 120 corresponding to the via holes 114 remain open (S34). In order to perform plating selectively on only the via hole 114 portions, the plating resist 118, which is a photosensitive material, may be stacked on other portions, with just the portions 120 corresponding to the via holes 114 opened. Furthermore, plating resist 119 may be applied also on the other side of the insulation substrate 106.

Here, the portions 120 corresponding to the via holes, i.e. the opened regions, may be sufficiently large such that there are no exposure tolerances, so that the plating layer 122 may readily be formed in the via holes 114.

When the via holes 114 and the regions where the via holes are opened are formed, electroplating may be performed, as in FIG. 5F, to form a plating layer 122 in the via holes 114 (S36). Here, the plating may be performed for a sufficient amount of time, so that the upper surface of the via holes 114 being plated may be made flat. In the case of performing electroplating in the via holes 114 to deposit the plating layer 122, the plating layer 122 may be formed to protrude out and cover a certain portion of the seed layer 116.

When electroplating is performed to form the plating layer 122 in the via holes 114, portions of the plating layer 122 may be removed, as in FIG. 5G, using an etchant, for example, such that the plating layer 122 is level with the surface of the insulation substrate 106 (S38). Here, making level refers to removing the plating layer 122 of the via holes 114 with an etchant, for example, such that the plating layer 122 is on substantially the same plane as the seed layer 116 formed on the surface of the insulation substrate 106. However, this does not mean that the plating layer 122 is mathematically in the exact same plane as the seed layer 116, and a certain degree of error is obviously permissible.

Next, as in FIG. 5H, the plating resist 118, 119, which is a photosensitive material that allows selective plating only on the portions 120 corresponding to the via holes formed in the insulation substrate 106, may be removed, after which the exposed seed layers 116, 117 may be removed (S40). In this way, the circuit patterns 104, 108 embedded and exposed at both sides of the insulation substrate 106 can be electrically connected with each other.

FIG. 6B is a plan view of the printed circuit board illustrated in FIG. 5H. As shown in the drawing, the via holes and the circuit pattern 104 may be connected, with the via holes and circuit pattern 104 embedded in the insulation substrate 106, so that there are no lands formed around the upper parts of the vias, and a greater amount of circuitry can therefore be implemented for the same area when forming circuitry between the vias.

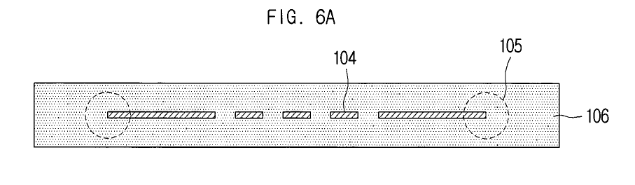

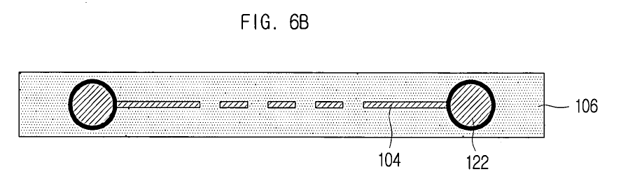

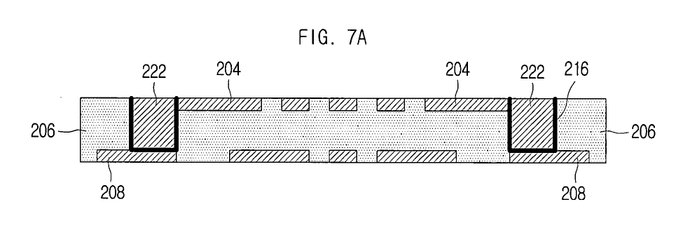

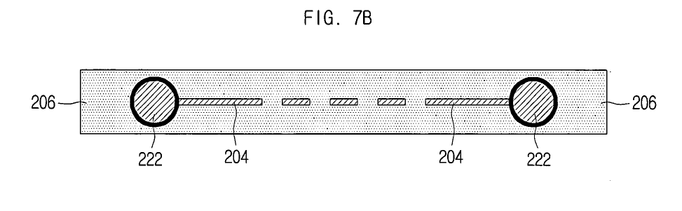

FIG. 7A is a cross-sectional view of a printed circuit board according to another embodiment of the invention, and FIG. 7B is a plan view of a printed circuit board according to another embodiment of the invention. In the drawings are illustrated circuit patterns 204, 208, an insulation substrate 206, a seed layer 216, and a plating layer 222.

In FIG. 7A, the through-hole that penetrates the insulation substrate 206 to electrically interconnect the circuit patterns 204, 208 on both sides of the insulation substrate 206 is formed as a PTH (plated through-hole), the manufacturing process of which can be implemented in the same manner as the manufacturing process illustrated with reference to FIGS. 5A to 5H. Thus, as the process is the same as that described above, redundant descriptions will not be repeated. By performing electroplating to form the plating layer 222 in the PTH's, there are no lands needed on either side of the insulation substrate 206 that protrude out, and as the circuit patterns 204, 208 are embedded in the insulation substrate, and PTH's are implemented that connect the circuit patterns 204, 208, as in FIG. 7A, a greater amount of circuitry may be implemented for a given area when forming circuitry between the vias.

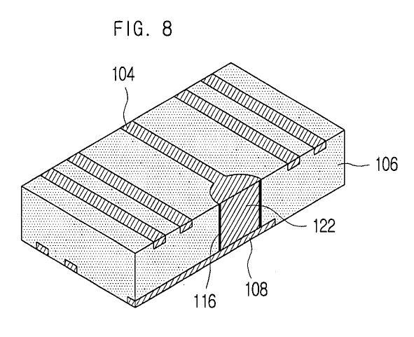

FIG. 8 is a perspective view of a printed circuit board according to an embodiment of the invention. In the drawing are illustrated circuit patterns 104, 108, a seed layer 116, an insulation substrate 106, and a plating layer 122. As illustrated in the drawing, the circuit patterns 104, 108 and the plating layer 122 of the via holes may be connected and may be embedded within the insulation substrate 106, such that no lands protruding out need to be formed around the via holes, whereby it is possible to form higher-density circuits, since more circuitry can be formed in the portions that would have been occupied by lands, and a fine-patterned printed circuit board may be implemented that has a high degree of integration, as more circuitry can be implemented for a given area of insulation substrate. Also, since there are no lands, there can be no lands cut due to the holes.

According to certain aspects of the invention as set forth above, it is possible to form high-density circuits, as circuitry may be formed in portions that might have been occupied by lands, and more circuitry may be implemented for a given area of insulation substrate, whereby a fine-patterned printed circuit board may be implemented that has a high degree of integration. Also, a printed circuit board can be produced which allows good signal transfers between layers and with which fine circuit patterns can be implemented with inexpensive costs.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a printed circuit board, the method comprising:
embedding a first circuit pattern and a second circuit pattern in one side and the other side of an insulation substrate;
forming a via hole by removing portions of the insulation substrate and the first circuit pattern; and
electrically connecting the first circuit pattern and the second circuit pattern by forming a plating layer in the via hole.

2. The method of claim 1, wherein the embedding comprises:
forming the first circuit pattern on a first carrier board having a first seed layer formed thereon, and forming the second circuit pattern on a second carrier board having a second seed layer formed thereon;
stacking the first carrier board on one side of the insulation substrate such that the first circuit pattern is embedded in one side of the insulation substrate, and stacking the second carrier board on the other side of the insulation substrate such that the second circuit pattern is embedded in the other side of the insulation substrate;
removing the first carrier board and the second carrier board; and
removing the first seed layer and the second seed layer.

3. The method of claim 1, wherein the electrically connecting comprises:
stacking a conductive third seed layer on a hole wall of the via hole;
stacking plating resist on a surface of the insulation substrate such that a portion corresponding to the via hole is opened;
forming the plating layer in the via hole;
removing a portion of the plating layer such that the plating layer is substantially level with a surface of the insulation substrate;
removing the plating resist; and
removing the exposed third seed layer.
